(19) United States
(12) Patent Application Publication
(10) Pub. No.: US 2015/0163957 A1
(43) Pub. Date: Jun. 11, 2015

(54) ARC RESISTANT VENTILATION SYSTEM FOR SWITCHGEAR

(71) Applicant: ABB Technology AG, Zurich (CH)

(72) Inventors: Erick Martinez-Cruz, San Luis Potosi (MX); Lyoji Jesus Yamaguchi, San Luis Potosi (MX); Erika Flores, San Luis Potosi (MX)

(73) Assignee: ABB Technology AG, Zurich (CH)

(21) Appl. No.: 14/623,716

(22) Filed: Feb. 17, 2015

Related U.S. Application Data
(63) Continuation of application No. PCT/EP2013/067420, filed on Aug. 21, 2013.
(60) Provisional application No. 61/692,010, filed on Aug. 22, 2012.

(51) Int. Cl. H05K 7/20

(52) U.S. Cl. CPC H05K 7/20009

(57) ABSTRACT

A ventilation system for switchgear has at least one chimney mounted to the roof of the switchgear enclosure. The at least one chimney has a flap mounted thereon for relieving pressure, hot gases, and particulate matter generated during an arc flash. The chimneys have grates in opposing side walls for ventilation of the switchgear. Under certain conditions, the grates allow the release of pressure below the threshold for raising the flaps. The flaps elevate when gases travel between the enclosure and an internal volume of said at least one chimney.

### FIELD OF INVENTION

The present application is directed to an arc resistant switchgear enclosure having a ventilation system.

### BACKGROUND

Switchgear is subject to fault conditions such as arc flashes during operation or maintenance of the switchgear. An arc flash occurs when electric current travels through the air between conductors or from a conductor to ground. An arc flash can result in serious injury or even death of personnel working in or near the switchgear due to the high temperatures of the gases and particulate matter expelled during an arc flash. The switchgear itself can be damaged or destroyed.

Ventilation systems have been provided as part of switchgear installations to contain and direct the arc flash away from personnel and the switchgear. However, known ventilation systems are expensive, labor-intensive to install, difficult to activate, and only relieve pressure from the switchgear enclosure during fault conditions.

### SUMMARY

An object of the present invention is to provide electrical switchgear having a ventilation system. The ventilation system is used to expel gases from the switchgear enclosure that houses at least one electrical device. The ventilation system has at least one chimney extending upward from a roof of the enclosure. A flap is attached to a top surface of the at least one chimney. The flap extends from a closed position to an open position when gases travel between the enclosure and an internal volume of the chimney.

### BRIEF DESCRIPTION OF THE DRAWINGS

In the accompanying drawings, structural embodiments are illustrated that, together with the detailed description provided below, describe exemplary embodiments of an arc resistant ventilation system for switchgear. One of ordinary skill in the art will appreciate that a component may be designed as multiple components or that multiple components may be designed as a single component.

Further, in the accompanying drawings and description that follow, like parts are indicated throughout the drawings and written description with the same reference numerals, respectively. The figures are not drawn to scale and the proportions of certain parts have been exaggerated for convenience of illustration.

FIG. 1 is a perspective view of a switchgear enclosure having a ventilation system of at least one chimney and embodied in accordance with the present invention;

FIG. 2 shows the at least one chimney mounted to a roof of the switchgear enclosure, the at least one chimney having side walls removed and a flap attached to each of the corresponding ones of the at least one chimney;

FIG. 3 shows one of the at least one chimney having the flap in a closed position and another one of the at least one chimney having the flap in an open position;

FIG. 4 is a side sectional view of the switchgear enclosure of FIG. 1;

FIG. 5 shows one of the at least one chimney in about a forty degrees open position, another one of the at least one chimney in a closed position, and an inset showing a rubber stopper installed in the flap;

FIG. 6A is a side view of the at least one chimney showing a grate and a flange of the flap; and

FIG. 6B is a side view of the at least one chimney having a flap with a forty-five degree bend.

### DETAILED DESCRIPTION

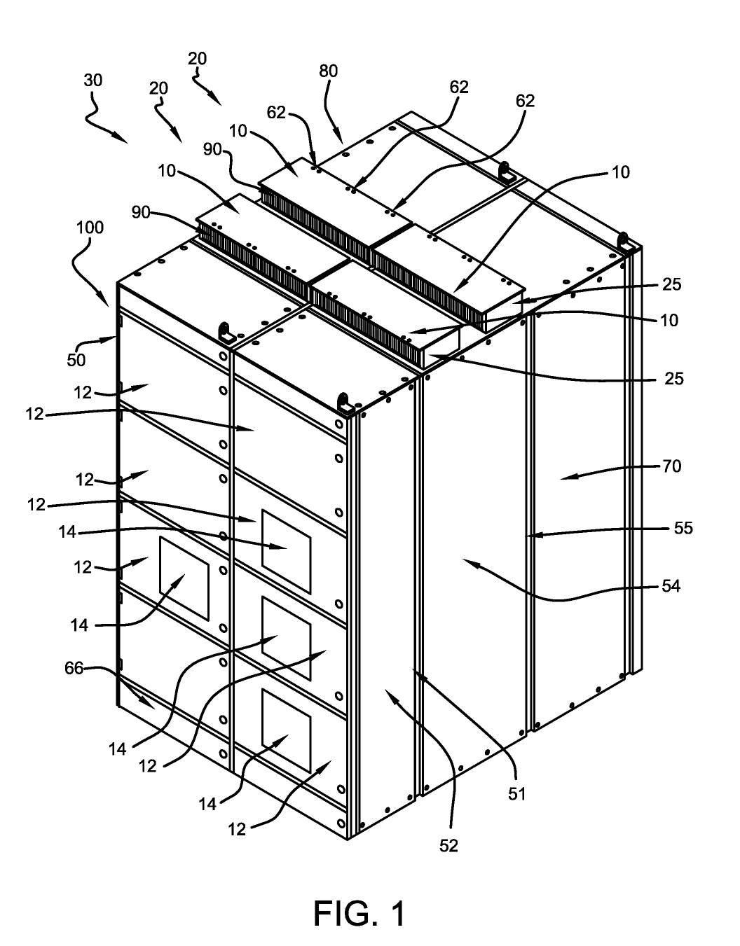

An exemplary low voltage electric switchgear unit is depicted in FIG. 1, having an enclosure 100 and a ventilation system 30. The ventilation system 30 is made up of at least one chimney 20 having a flap 10 mounted thereto and serves to expel the hot gases and particulate matter of an arc flash from the enclosure 100. Low voltage, as used herein, refers to voltages that do not exceed 600 volts. Although the low voltage electric switchgear unit (hereinafter “switchgear”) is depicted, it should be understood that the enclosure 100 and ventilation system 30 may be adapted for use in medium voltage switchgear applications that range from about 600 volts to about 38 kV.

The enclosure 100 has four walls, a base 66 and a roof 80. The enclosure 100 houses a cable section 70, a bus bar section 54, and a device section 52. The cable section 70 houses cables that electrically connect the utility service or other power source to bus bars 88.

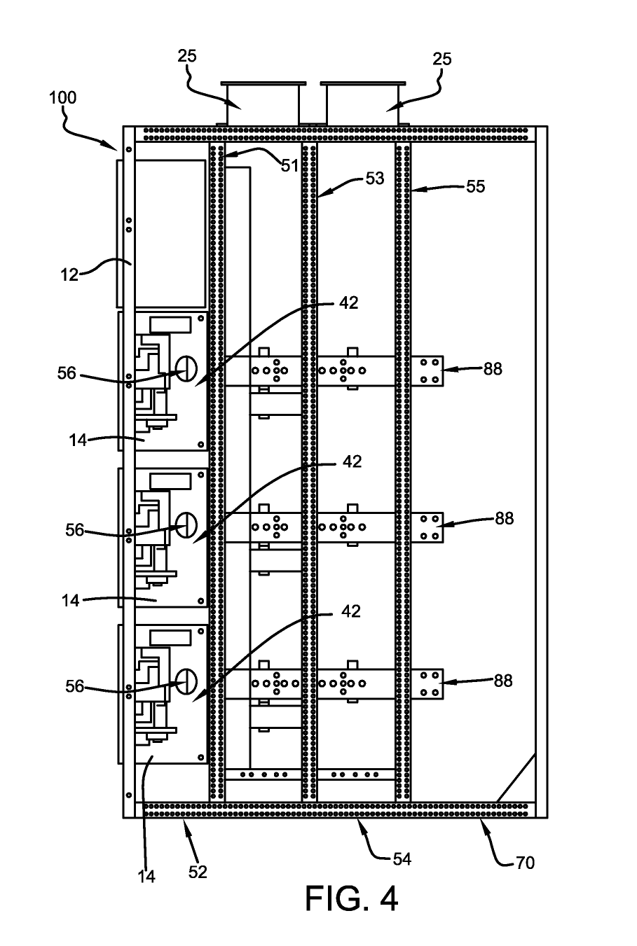

Referring now to FIG. 4, the bus bar section 54 houses bus bars 88, typically formed from copper, and connections between the bus bars 88 and at least one electrical device 14. The bus bar section 54 also acts as a vertical ventilation path to direct and/or channel hot gases and particulate matter generated during an arc flash or other pressure-generating event into the ventilation system 30.

The bus bar section 54 is located between walls 51, 55. Walls 51, 55 are provided as solid walls formed of glass fiber-reinforced plastic (GFRP) having openings for bus bars 88, cable connections and other connections. Alternatively the walls 51, 55 are formed from panels of GFRP or sheet metal that are connected together, the panels having openings for bus bars 88 and various connections. The walls 51, 55 may be provided with grates to allow ventilation of the hot gases and particulate matter generated during an arc flash into the bus bar section 54 where the gases then enter or are directed into an internal volume 34 of the at least one chimney 20.

The device section 52 has compartments 12 for housing at least one electrical device 14 such as molded case circuit breakers, air circuit breakers, ohmmeters, ammeters, multi-meters, relays, programmable logic controllers, potential transformers, control power transformers, and other types of circuit breakers and testing devices suitable for the application.

Alternatively, one or more of the compartments 12 may be empty or serve as placeholders for a later-installed at least one electrical device 14. The exemplary switchgear enclosure 100 shown has four compartments 12 in each column, otherwise referred to as 4-high when occupied by electrical devices 14. However, it should be understood that different configurations and numbers of electrical devices 14 may be utilized depending on the application.

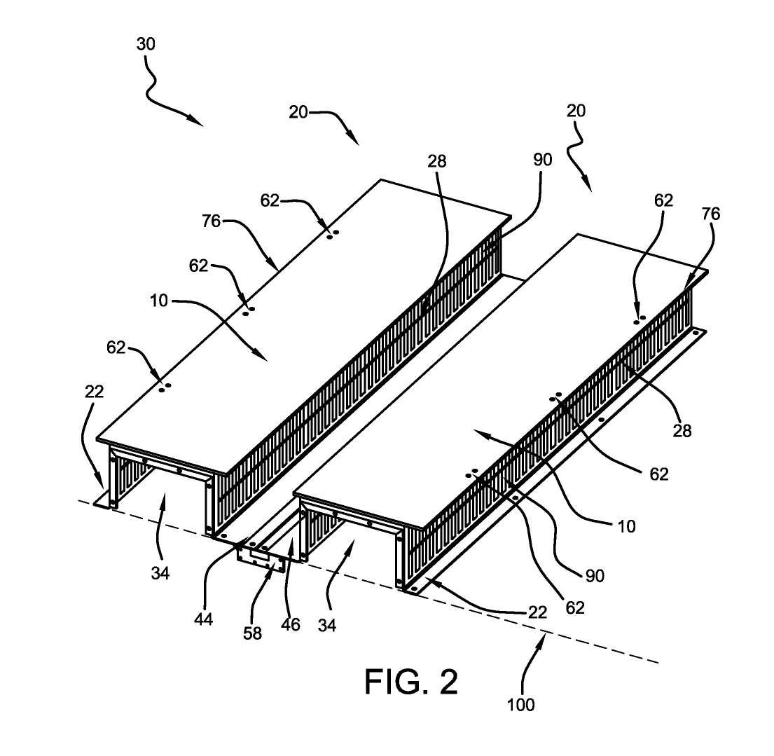

Referring now to FIG. 2, the at least one chimney 20 is shown attached to and extending upward from a roof 80 of the enclosure 100. The at least one chimney 20 is typically mounted above the bus bar section 54 as most faults or pressure buildup occur in the bus bar section 54 or are otherwise channeled into the bus bar section 54 and are relieved through the at least one chimney 20. It should be understood that the at least one chimney 20 may be mounted to the roof 80 above other sections 52, 70 of the switchgear enclosure 100.

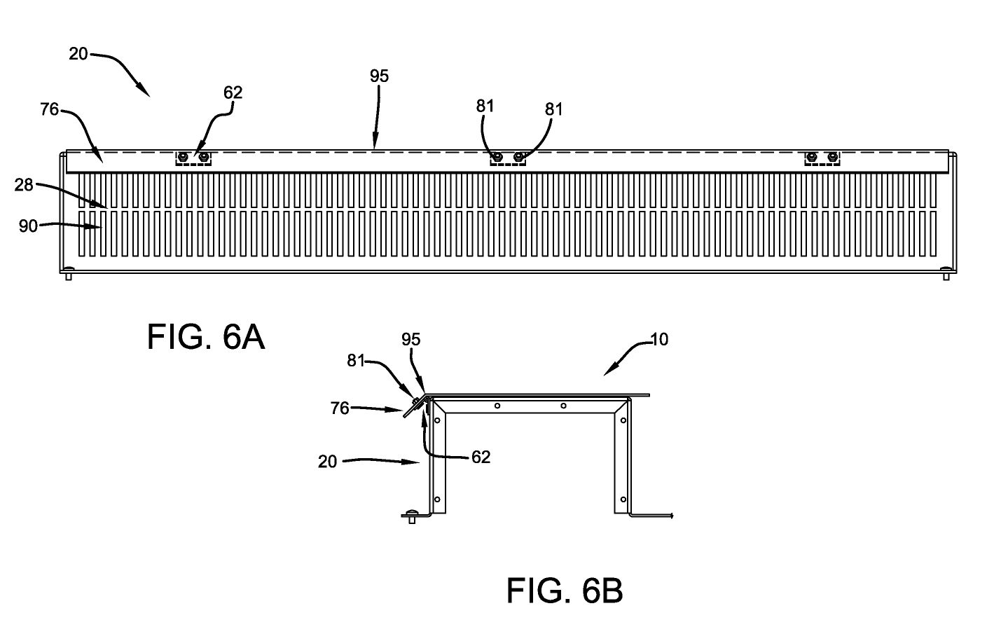

The at least one chimney 20 has a flap 10 attached thereto. More particularly, the flap 10 is mounted to a top edge 84 of the at least one chimney 20 by hinges 62. The hinge 62 is a standard hinge having two leaves and a pin connecting the two leaves together. One of the hinge leaves 62 is attached to the flap 10 and the other of the hinge leaves is attached to or near the top edge 84 of the at least one chimney 20. Alternatively, one of the hinge leaves 62 is attached to the flap 10 and the other of the hinge leaves 62 is attached to a flat portion of a side wall 28 of the at least one chimney 20 as shown in FIG. 6A. There are typically three hinges 62 per flap 10 mounted along the flange 76, however, it should be understood that other numbers of hinges 62 and hinge 62 placements may be used depending on the application.

The at least one chimney 20 has one or more walls. Although the at least one chimney 20 is depicted in FIGS. 1-4 as rectangular and having four side walls 25, it should be understood that the at least one chimney 20 may be round, thus having one cylindrical wall. In the case of a rectangular at least one chimney 20, the longer two opposing side walls 25 have grates 90 disposed thereon. The grates 90 may be embodied as a single row of openings or two rows of openings or any other arrangement that allows the product of an arc fault to escape from the enclosure 100. The shorter opposing side walls 25 are formed of a flat sheet metal and act with the grates 90 to form the internal volume 34 enclosed by the at least one chimney 20. The grates 90 provide an exit path for the gas and particles generated during an arc flash or fault, thereby relieving a portion of the pressure generated during operation of the switchgear or during an arc flash.

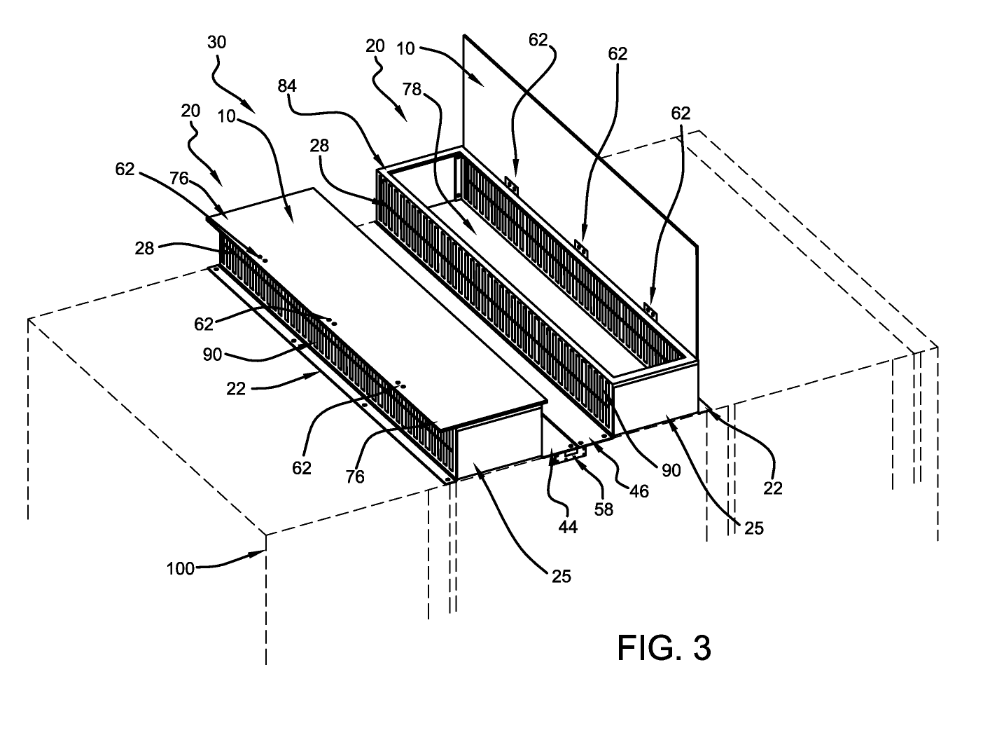

Referring now to FIG. 3, the at least one chimney 20 of the ventilation system 30 has grates 90 disposed on opposing side walls. The at least one chimney 20 provides an internal volume 34 for arc flash containment as well as a path from the arc flash-originating section 52, 54, 70 of the switchgear enclosure 100 for expelling hot gases, particulate matter and pressure through the at least one chimney 20. It should be understood that depending on the configuration of the switchgear any number of chimneys suitable for the application may be utilized, however, a preferred embodiment utilizes two chimneys.

Referring now to FIGS. 2 and 3, the at least one chimney 20 is shown mounted to a roof 80 of the enclosure 100. The roof 80 of the enclosure 100 has an opening 78 corresponding to the at least one chimney 20, the opening 78 being generally rectangular in shape. The at least one chimney 20 completely encloses the opening 78 and creates the internal volume 34. The at least one chimney 20 is mounted near the edge of the openings 78 of the enclosure 100 by attaching flange sections 22, 44, 46 and a bracket 58 to the roof 80 of the enclosure 100 and securing the flange sections 22, 44, 46 and bracket 58 to the roof of the enclosure using rivets, bolts or another type of fastener.

Lower pressure faults may be relieved entirely through the grates 90 without elevating or even partially raising the flaps 10. In one embodiment, lower pressure faults, such as faults generating gases having a pressure below 14.5 psi, cause the flaps 10 to elevate only partially from the top surface 84 of the corresponding at least one chimney 20.

Referring now to FIG. 3, a flap 10 of the at least one chimney 20 is depicted in an open position. Each of the flaps 10 open no greater than about 90 degrees from the plane in which the top surface 84 of the corresponding chimney 20 is located. In an embodiment having two of the at least one chimney 20, the flaps 10 open away from one another when a predetermined pressure threshold has been reached, triggering the raising of the flaps 10. More particularly, the flaps 10 elevate when gases travel between the enclosure 100 and the internal volume 34 of the at least one chimney.

A predetermined pressure threshold of about 14.5 psi or greater causes the flaps 10 to fully open in one embodiment. It should be understood that the ventilation system 30 is capable of withstanding more or less pressure than the predetermined pressure threshold, depending on the application. By way of non-limiting example, the hinges may be modified to allow an increased or decreased opening radius of the flaps 10 or the thickness or weight of the flaps 10 may be increased or decreased.

With continued reference to FIG. 3, one of the flaps 10 is shown in a fully open position which is about ninety degrees from a horizontal plane formed or as measured by the top surface 84 of the chimney 20. The flaps 10 when raised or fully open, are prevented from extending beyond ninety degrees from the top surface 84 of the chimney 20 by flanges 76 that extend 35 mm beyond the edge of the top surface 84 of the at least one chimney 20. In one embodiment, the flaps 10 are prevented from opening more than 80 degrees in relation to the horizontal plane of the top surface 84.

The edge of the flange 76 contacts the grate 90 at about the position between the two rows of openings of the grate 90 of side wall 28. When the flanges 76 are in contact with the grates 90, the flanges 76 prevent the flaps 10 from moving to a position where the flaps 10 are greater than ninety degrees from a horizontal plane as measured by a plane of the top edge 84 of the at least one chimney 20.

The flaps 10 return to a closed position by gravitational forces once the pressure of the fault is relieved. Additionally, the hinges 62 may be designed to self-close the flaps 10 using the force of contact between the flaps and the grates 90 and after the release of pressure from the bus bar 54 section as discussed below. The flaps 10, when in a closed position, prevent objects and personnel working on the switchgear from falling into the enclosure 100.

Referring now to FIG. 4, a side sectional view of the switchgear enclosure 100 having the at least one chimney 20 mounted to the roof 80 is shown. Circuit breakers 42 are connected through contacts 56 to bus bars 88. An arc flash may occur in any of the switchgear sections 52, 54, 70. Arc faults occurring in the bus section 54 are channeled upward through a ventilation path created by bus section 54 walls 51, 55 which act as a duct to channel and direct the arc flash vertically into the internal volume 34 and to exit the at least one chimney 20.

Arc faults occurring in the device section 52 and the cable section 70 are typically vented through grates in the walls 51, 55 to then follow the ventilation path created by the bus section 54 as previously described.

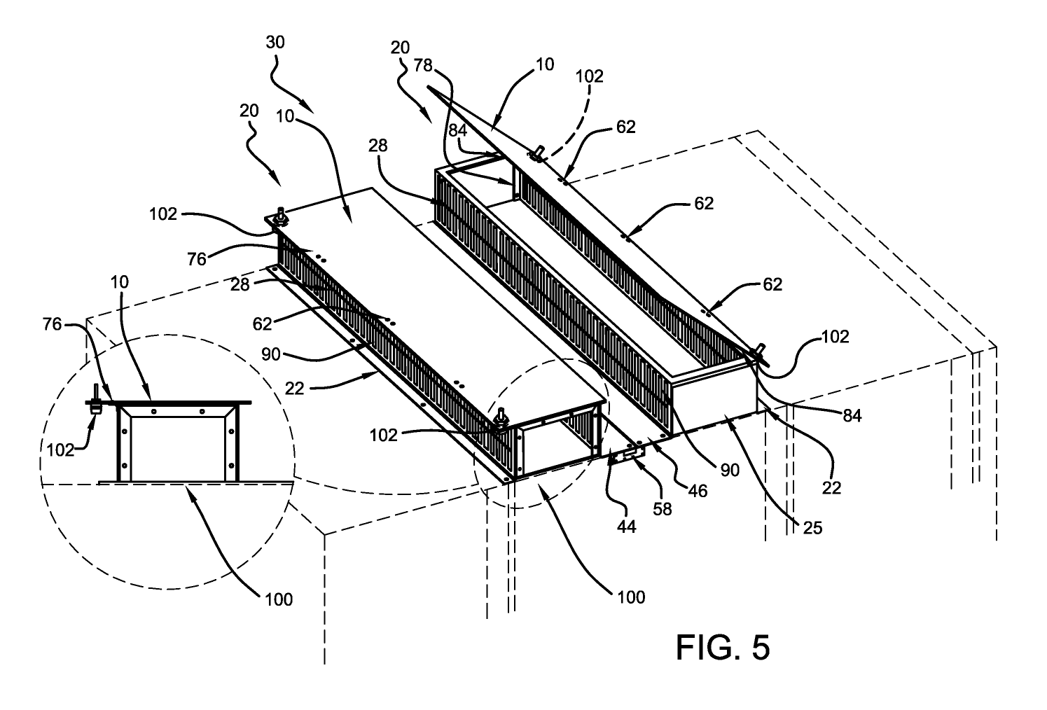

With reference now to FIG. 5, an embodiment of the ventilation system 30 is shown having a stopper 102 disposed near the corners of the flaps 10 located along the flange 76. In one embodiment, the stopper 102 is installed near the two corners of each flap 10 that lie along the flange 76. It should be appreciated that one or any other number of stoppers 102 may be installed along the flange 76 or at another location on the flap 10 where contact is made between the flap 10 and another surface, including but not limited to the top edge 84 of the at least one chimney 20.

The stopper 102 is formed from an elastomeric material and has a diameter of about 16 mm and a height of about 7 mm. When the flaps 10 move from the closed position to about a forty degrees open position due to the force of an arc fault or other pressure generating event, the stopper 102 will contact the grate 90. The contact between the stopper 102 and the grate 90 causes the flaps 10 to close.

The stopper 102 acts as a spring mechanism, so that when the stopper 102 contacts the grate 90, the force generated from the contact between the stopper 102 and the flap 10, will return the flap 10 to a closed position. In this manner, the self-closing flaps 10 serve as a safety feature because the operator does not have to close the flaps 10 manually after the pressure and/or hot gases and particles associated with an arc flash have exited the switchgear 100.

With reference now to FIG. 6, the flap 10 is shown as having a bend 95. The bend 95 is about forty-five degrees as measured from the horizontal surface of the flap 10 when the flap 10 is in a closed position. The bend 95 provides a self-closing feature for the flaps 10 that allows the flange 76 to contact the grate 90 when the flap 10 is at a forty-five degree angle in relation to a horizontal plane as measured from the plane in which a closed flap 10 would lie. In one embodiment, the bend 95 and the stopper 102 are both provided to achieve a self-closing mechanism for the flaps 10.

While the present application illustrates various embodiments, and while these embodiments have been described in some detail, it is not the intention of the applicant to restrict or in any way limit the scope of the appended claims to such detail. Additional advantages and modifications will readily appear to those skilled in the art. Therefore, the invention, in its broader aspects, is not limited to the specific details, the representative embodiments, and illustrative examples shown and described. Accordingly, departures may be made from such details without departing from the spirit or scope of the applicant's general inventive concept.

What is claimed is:

1. An electric switchgear comprising:
an enclosure; and
a ventilation system for expelling gases from an enclosure housing at least one electrical device, said ventilation system having:
at least one chimney having one or more walls, said at least one chimney extending upward from a roof of said enclosure; and
a flap attached to a wall of said at least one chimney, said flap elevating when said gases travel from the enclosure and into an internal volume of said at least one chimney.

2. The switchgear of claim 2 wherein a set of opposing walls of each of said at least one chimney has grates disposed thereon.

3. The switchgear of claim 1 wherein when said flap raises, said flap opens outward no more than ninety degrees in relation to a top surface of said chimney.

4. The switchgear of claim 2 wherein said flap is prevented from opening beyond ninety degrees in relation to a horizontal plane along a top surface of said chimney when a flange of said flap contacts said grate.

5. The switchgear of claim 1 wherein said enclosure further comprises a bus bar section, said bus bar section providing a ventilation path to an internal volume of the at least one chimney.

6. The switchgear of claim 2 wherein said grates relieve pressure in the enclosure without activating said flaps when the pressure inside the enclosure is less than a predetermined pressure threshold.

7. The switchgear of claim 6 wherein said predetermined pressure threshold is 14.5 psi.

8. The switchgear of claim 1 wherein a stopper is attached to said flap, said stopper contacting a wall of said at least one chimney when said flap is elevated at least 40 degrees in relation to a horizontal plane formed by a top surface of said at least one chimney wall.

9. The switchgear of claim 1 wherein a bend is provided in said flap and a flange of said flap contacts a wall of said at least one chimney when said flap is elevated at least 45 degrees in relation to a horizontal plane formed by a top surface of said at least one chimney wall.

10. The switchgear of claim 9 wherein said bend is at least 45 degrees in relation to the horizontal plane formed by the portion of said flap.

11. The switchgear of claim 8 wherein said stopper is formed of an elastomeric material.
